(19) United States
(12) Patent Application Publication
(10) Pub. No.: US 2012/0168853 A1
(43) Pub. Date: Jul. 5, 2012

(54) SEMICONDUCTOR NON-VOLATILE MEMORY DEVICE

(76) Inventors: Hua Ji, Shanghai (CN); Min-Hwa Chi, Shanghai (CN); Fumitake Mieno, Shanghai (CN); Seanfuxiong Zhang, Shanghai (CN)

(21) Appl. No.: 13/419,943

(22) Filed: Mar. 14, 2012

Related U.S. Application Data
(63) Continuation-in-part of application No. 12/141,040, filed on Jun. 17, 2008, now Pat. No. 8,158,512.

(30) Foreign Application Priority Data
Jun. 22, 2007 (CN) 200710042461.5

(51) Int. Cl. H01L 29/792

(52) U.S. Cl. 257/324; 257/E29.309

(57) ABSTRACT

A semiconductor non-volatile memory (NVM) device, comprising: a semiconductor substrate; a three-layer stack structure of medium layer-charge trapping layer-medium layer disposed on the semiconductor substrate; a gate disposed above the three-layer stack structure; a source and a drain disposed in the semiconductor substrate at either side of the three-layer stack structure; wherein the charge trapping layer is a dielectric layer containing one or more discrete compound clusters formed by atomic layer deposition (ALD) method.

### CROSS REFERENCE TO RELATED APPLICATIONS

This application is a continuation-in-part of U.S. patent application Ser. No. 12/141,040, entitled “Atomic Layer Deposition Method and Semiconductor device Formed by the Same”, filed on Jun. 17, 2008, which claims the priority of Chinese Patent Application No. 200710042461.5, entitled “Atomic Layer Deposition and Semiconductor device Formed by the Same”, and filed on Jun. 22, 2007, each of which is incorporated herein by reference in its entirety.

### FIELD OF THE INVENTION

The present invention relates to semiconductor technology, and more particularly, to a semiconductor non-volatile memory device.

### BACKGROUND OF THE INVENTION

Atomic layer deposition (ALD) is originally referred to as Atomic Layer Epitaxy (ALE), and is also termed as Atomic Layer Chemical Vapor Deposition (ALCVD).

ALD involves a successive deposition of a plurality of monolayers on a semiconductor substrate within a deposition chamber typically maintained at a negative pressure (sub-atmospheric pressure). An exemplary method comprises the following steps: feeding a first vaporized precursor into a deposition chamber to form a first monolayer 110 on the semiconductor substrate 100 placed in the deposition chamber, as shown in FIG. 1, where the ALD process continues until the entire substrate surface is covered by the monolayer 110 in a saturation manner. Note that only one monolayer is deposited on surface and further stacking of monolayers is extremely slow due to un-favored chemical energy. This is in “self-stopping” manner. Thereafter, ceasing the flow of the first vaporized precursor, and flowing a purge gas through the chamber to remove all remaining first precursor which is not adhering to the semiconductor substrate 100 from the chamber, as shown in FIG. 2. A high quality, uniform, and closely packed monolayer on substrate is formed with specific thickness (or height) determined by the atomic monolayer and it is also conformal over surface topology (i.e. same thickness of film over steps, trenches, . . . etc. on the substrate); all these are unique characteristics of ALD deposition than other thin film deposition methods, e.g. chemical vapor deposition (CVD) or physical vapor deposition (PVD), where their deposition process is not in self-stopping manner. Subsequently, flowing a second vaporized precursor which is different from the first precursor into the deposition chamber to form a second monolayer 120 on the first monolayer 110 also in saturation manner, the second monolayer 120 can react with the first monolayer 110, as shown in FIG. 3; and ceasing the flow of the second precursor, and flowing a purge gas through the chamber to remove all remaining second monolayer 120 which is not adhering to the first monolayer 110, as shown in FIG. 4. The deposition of the first and the second monolayers, therefore, formed a 1^{st} atomic “compound layer”; this process is also in self-stopping manner so that each “compound layer” is deposited one at a time. The above ALD deposition of the “compound layer” (i.e. the deposition of the 1^{st} and 2^{nd} monolayers) can be repeated until a stack of multiple atomic compound layers with desired thickness formed on the semiconductor substrate. The resulted multiple compound layers are also conformal over surface topology as unique characteristics of ALD. The ALD method is a preferred process when topology occurs with a high aspect ratio of depth and width on semiconductor surface than other conventional processes for manufacturing a semiconductor device.

However, if the above stack of multiple compound layers, as formed by alternating deposition of the first and the second monolayers in continuous and saturation manner, serves as the charge-trapping material in the charge-trap type non-volatile memory (NVM), then the re-distribution or leakage of charge in latitudinal direction can occur and result in inferior retention of charge (i.e. charge is desirably stored locally near the drain and source for representing the 2-bit data).

Furthermore, such an ALD layer formed in continuous and saturation manner is easier to be re-crystallized by the subsequent thermal cycles in CMOS process. As known, a re-crystallized dielectric (e.g. Hf-oxide) layer results in higher gate leakage current and poorer transistor reliability when it serves as the gate dielectric in CMOS transistors.

When the semiconductor NVM device is continuously scaled in size, the requirement for the localized charge storage becomes more stringent. The charge-trapping film in NVM device is typically capped with dielectric layers on top and bottom, i.e. a 3-layer-stack structure of “dielectric layer—charge trapping (compound) layer—dielectric layer”. In prior art, it is proposed that the use of a charge trapping layer consisting of discrete islands (also referred to as nano-dots or quantum dots) embedded within dielectric material is preferred for charge storage than a continuous compound layer for better suppressing the lateral charge re-distribution or leakage. However, in the prior art, the discrete islands (or nano-dots) in the charge trapping layer is generally formed by chemical vapor deposition (CVD) or physical vapor deposition (PVD), where the nano-dots vary in size in a large range and difficult to control. The large variations of nano-dots leads to large variations of cell's threshold voltage (Vt) after memory operations (write or erase); this further leads to poor memory performance.

### SUMMARY OF THE INVENTION

To resolve the above-mentioned problem, the present invention provides a semiconductor non-volatile memory (NVM) device with a three-layer stack structure of “dielectric layer-charge trapping layer-dielectric layer”, wherein the charge trapping layer has discrete compound clusters with uniform size and leads to superior charge storage capability and stability.

In one aspect according to the present invention, there is provided a method for manufacturing a semiconductor NVM device, including steps of: providing a semiconductor substrate; forming a three-layer stack structure of “dielectric layer-charge trapping layer-dielectric layer” on the semiconductor substrate; forming a gate above the three-layer stack structure; forming a source and a drain in the semiconductor substrate at either side of the three-layer stack structure; wherein the charge-trapping-layer formed by ALD method includes a layer of nano-sized discrete compound clusters embedded in the dielectric layer. The compound clusters are metal-oxide or metal and equal in size (typically 3 nm-7 nm in diameter) and thickness (typically 1 nm-10 nm in height) as determined by the material species and process. A dielectric material, typically Si-nitride or Si-oxide, closely surrounds the compound clusters.

In another aspect according to the present invention, a semiconductor NVM device is provided, which includes: a semiconductor substrate; a three-layer stack of “dielectric layer-charge trapping layer-dielectric layer” disposed on the semiconductor substrate; a gate disposed above the three-layer stack; a source and a drain disposed in the semiconductor substrate at either side of the three-layer stack; wherein the charge-trapping-layer formed by ALD method includes nano-sized discrete compound clusters inlayed or embedded in dielectric material. The compound clusters usually consist of metal-oxide or metal and they are equal in size (typically 3 nm-7 nm) and thickness (typically 1 nm-10 nm) as determined by the material species and process. The dielectric layer closely surrounds the compound clusters.

The present invention, compared with the prior art, has the following advantages:

The embodiments according to the present invention provides a method for manufacturing a semiconductor NVM device, by which discrete compound clusters are embedded in dielectric material as the charge trapping layer. The discrete compound clusters are of the same size (typically 3 nm-7 nm) and thickness (typically 1 nm-10 nm) and are uniformly distributed with the dielectric material closely surrounded the compound clusters for blocking the charge transfer between clusters (and reducing the lateral charge re-distribution and leakage among clusters). Thus it leads to improved capability of local charge storage and better data retention of NVM device. The small and equal size and thickness of discrete charge-trapping compound clusters are critical in maximizing the density of change storage (by small size and large density) and can reduce the variations of memory cell threshold voltage (Vt) after write/erase operations (by small variations of size/thickness).

The embodiments according to the present invention further provides a semiconductor NVM device which includes a three-layer stack of “dielectric layer-charge trapping layer-dielectric layer”, wherein the charge trapping layer contains discretely distributed compound clusters formed by atomic layer deposition (ALD) method embedded in dielectric material. The compound clusters are equal in the same size (typically 3 nm-7 nm) and thickness (typically 1 nm-10 nm) as determined by the atomic species and process.

### BRIEF DESCRIPTION OF THE DRAWINGS

FIGS. 1 to 4 are schematic views illustrating an ALD process according to the prior art.

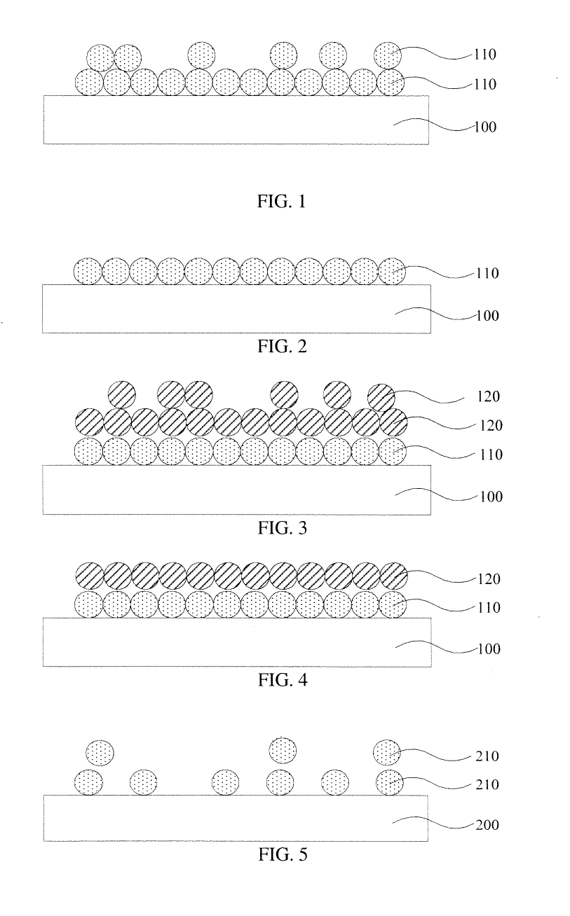

FIGS. 5 to 14 are schematic cross-sectional views of intermediate structure in a method for manufacturing a charge trapping layer according to an embodiment of the present invention.

FIGS. 15 is a schematic cross-sectional view of intermediate structure in another method for manufacturing a charge trapping layer according to another embodiment of the present invention;

FIG. 16 is a schematic view of flow chart illustrating a semiconductor NVM device formation process according to an embodiment of the present invention.

FIG. 17 is a schematic view of flow chart illustrating a charge-trapping-layer formation process according to an embodiment of the present invention.

FIG. 18 is a schematic view of flow diagram illustrating a process for forming a compound monolayer according to an embodiment of the present invention.

FIG. 19 is a schematic view of flow chart illustrating a process for forming a first dielectric monolayer to fill in the spacing in-between a first compound nuclei and to cover the first dielectric mono-atomic layer and the discrete compound nuclei according to an embodiment of the present invention.

FIG. 20 is a schematic view of another flow diagram illustrating a process for forming a charge trapping layer according to an embodiment of the present invention.

FIG. 21 is a schematic structural view of a semiconductor device according to an embodiment of the present invention.

### DETAILED DESCRIPTION OF THE EMBODIMENTS

One object of the present invention is to provide a method for forming a semiconductor non-volatile memory (NVM) device including forming a layer of discrete compound clusters (usually metal-oxide or metal) embedded in dielectric material (usually Si-oxide or Si-nitride or a combination thereof), wherein the compound clusters (or nano-dots, quantum dots) are almost equal in diameter (size) and height (thickness) in a range of 3 nm-7 nm and 1 nm-10nm respectively as determined by the material species and process. The density of compound clusters can be controlled by adjusting the ALD process parameters, e.g. the operating pressure, temperature, and process time. The density of discrete compound clusters is related to the size (typically 3 nm-7 nm) and spacing among them (typically 1 nm-3 nm) and is to be maximized.

Another object of the present invention is to provide a semiconductor NVM device with a three-layer stack of “dielectric layer-charge trapping layer-dielectric layer”, wherein the charge trapping layer includes a dielectric layer (usually Si-oxide or Si-nitride or a combination of both) containing discrete compound clusters (usually metal-oxide or metal) embedded in the dielectric material.

It is known that the compound clusters shall be formed in equal size and as small size as possible for scaled cell, so that the total amount of charges stored in the charge-trapping layer in memory cell can be maximized. In below, the embodiment according to the present invention provides an ALD method for the formation of charge-trapping-layer with discrete compound clusters equal in size and thickness (i.e. very tight distribution of size and thickness of compound clusters) for better charge storage capability and small variations of cell Vt.

The above objects, features and advantages of the present invention will become better understood with respect to the following description of the preferred embodiments given in conjunction with the accompanying drawings.

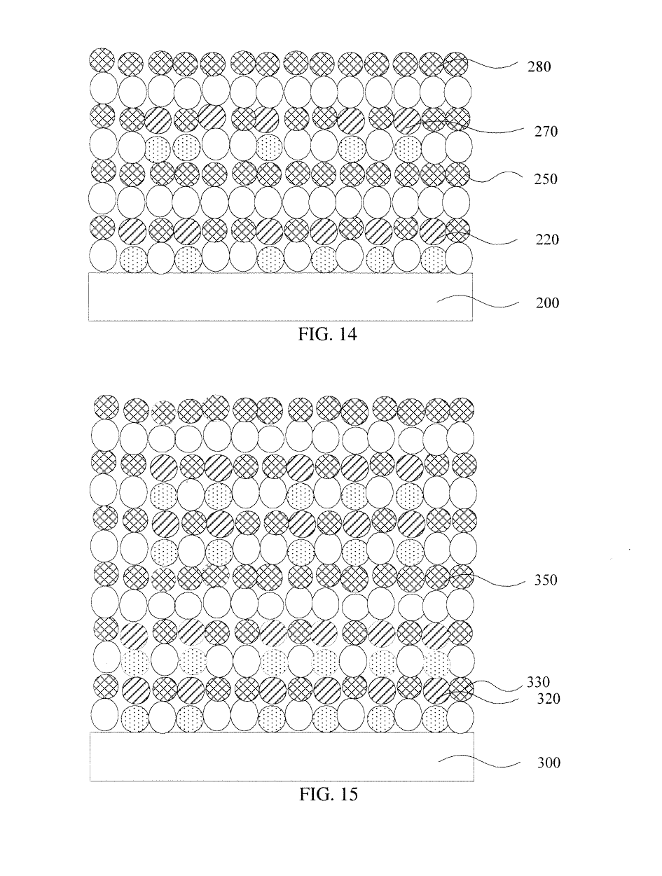

A method for forming a semiconductor NVM device is provided in this embodiment. Referring to FIG. 16, the method includes the following steps: step S1, providing a semiconductor substrate; step S2, forming a three-layer stack of “dielectric layer-charge trapping layer-dielectric layer” on the semiconductor substrate, wherein the charge trapping layer is a dielectric layer containing discretely distributed compound clusters; step S3, forming a gate above the three-layer stack; step S4, forming a source and a drain in the semiconductor substrate at either side of the three-layer stack structure; wherein the charge-trapping-layer is a dielectric layer containing discrete compound clusters.

The discrete compound clusters usually consists of metal-oxide or metal with the same size (typically 3 nm-7 nm) and thickness (typically 1 nm-10 nm).

The semiconductor substrate 200 may be selected from various semiconductor materials known to those skilled in the art, including silicon or silicon germanium (SiGe) with monocrystal or polycrystal structures, ion-doped Si or SiGe such as N-doped or P-doped Si or SiGe, compound semiconductor such as silicon carbide (SIC), indium antimonide (InSb), lead telluride (PbTe), indium arsenide (InAs), indium phosphide (InP), gallium arsenide (GaAs) or gallium telluride (GaTe), or a combination thereof, or silicon-on-insulator (SOI). The semiconductor substrate may be an initial semiconductor substrate, or a semiconductor substrate comprising various semiconductor devices and wirings therein.

Material of the dielectric layer in the three-layer stack structure may include insulation material, such as silicon oxide (Si-oxide), silicon nitride (Si-nitride), germanium oxide (Ge-oxide), germanium nitride (Ge-nitride), aluminum oxide (Al-oxide) or the like. The deposition of dielectric layer in the three-layer stack can be performed by conventional ALD technique as known to those skilled in the art.

Material of the gate may be a multilayer structure containing conductive semiconductor materials (such as doped Si or Ge), metals, metal-silicides, or a combination thereof. The gate can be performed by any technique in the prior art known to those skilled in the art.

The source and the drain are disposed at either side of the three layer stack structure, and are in the semiconductor substrate. The source and the drain may be formed by doping the semiconductor substrate. The doping ions may be one or more ions of phosphorus (P), arsenic (As), boron (B), indium (In), or antimonide (Sb).

The charge trapping layer is a dielectric layer containing discrete compound clusters embedded therein. The compound clusters are usually consisting of metal-oxide or metal with the same size (in 3 nm-7 nm) and thickness (in 1 nm-10 nm). The compound clusters are used to store charges.

The charge-trapping-layer can be formed by ALD process according to one embodiment of the invention. In the manufacturing process of the charge trapping layer, it is needed to form the dielectric layer and the discrete compound clusters in separate steps. Firstly, the compound clusters can be formed by ALD in non-saturation manner, then the dielectric layer can be formed by ALD in saturation manner to fill in the spacing surrounding the discretely distributed compound clusters. In a non-saturation manner of ALD process (referred to as non-saturation ALD), compound monolayer nuclei are formed and discretely deposited on surface. In a saturation manner of ALD process (referred to as saturation ALD), a high quality, uniform, and closely packed dielectric are formed surrounding the compound nuclei. By using the saturation ALD (for the dielectric layer) and the non-saturation ALD (for forming the compound nuclei) alternately, the discretely distributed compound nuclei or clusters are formed with tightly surrounded by the dielectric material, thereby forming a compact, integrated charge-trapping-layer with discrete compound clusters uniformly embedded.

The discrete compound clusters can be formed by stacking one or more compound monolayers together. When at least two monolayers of compound are stacked, the compound nuclei of the monolayers will stack together on top of each other correspondingly (as determined by chemical energy of species), therefore, the lateral size of compound clusters is the same (typically 3 nm-7 nm), and the height or thickness (typically 1-10 nm) of compound clusters is determined by the number of the times of repeating formation of compound nuclei of monolayers. Specifically, the compound clusters are metal compound (such as Hf-oxide, WN, Al₂O₃, or ZrO,) or metals, and desirably small in lateral diameter (size) and dense (but not touching each other).

The dielectric material in the charge trapping layer fills in-between the spacing of the compound clusters and continuously covers the surface by prolonged process time and adjusting process parameters. The dielectric material typically includes Si, Oxygen, and Nitrogen species (to form Si-oxide, or Si-nitride, or mixture Si-oxynitride), The dielectric material with more Oxygen content can be favorable to fill-in the spacing of discrete compound clusters; alternatively, the dielectric material with more Nitrogen content will be favorable to cover the top surface of the compound clusters and cover the dielectric material filling in the gap of discrete compound clusters of one layer. If the compound clusters needed to be higher (in vertical direction but still small in lateral size), it can be formed by repeating the ALD for compound monolayers and the “fill-in” of dielectric material with more Oxygen content, then performing the “surface-cover” of dielectric layer with more Nitrogen content. This completes the 3-layer stack structure for charge-trapping type NVM memory.

In one embodiment of the present invention, a charge trapping layer with discretely distributed compound clusters embedded within a dielectric material is provided, wherein the size of each cluster inlayed in the charge trapping layer is substantially the same size, and the thickness (or height) of each cluster is substantially the same as one compound nuclei. The lateral size of each discrete compound cluster is determined chemically of the metal compound, typically the size of a few atoms.

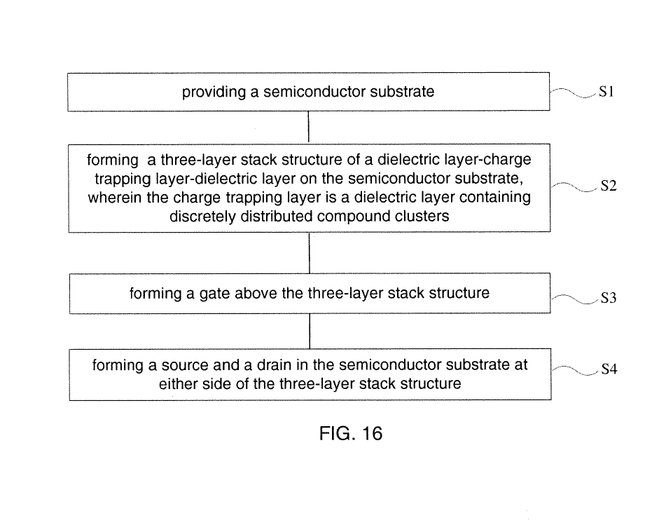

Specifically, referring to FIG. 17, the charge trapping layer in the step S2 can be formed as following: step S20, placing the semiconductor substrate in an ALD chamber and forming an initial dielectric layer thereon; step S21, forming a first compound monolayer on the dielectric layer on the semiconductor substrate, wherein the first compound monolayer consists of discrete compound nuclei; step S22, forming a first dielectric monolayer to fill in the spacing in-between the compound nuclei of the first compound monolayer and cover the surface of the first compound monolayer above the semiconductor substrate. Note that, the first dielectric monolayer not only fills the spacing between the compound nuclei (by Oxygen rich content), but also covers the surface of both compound and fill-in dielectric material (by Nitrogen rich content); step S23, repeating the step S21 for forming the compound monolayer and the step S22 for forming the fill-in and surface-cover dielectric monolayer successively till the desirable total thickness of charge trapping layer structure achieved. It is noted that the entire step S2 for forming the charge-trapping stack can be performed in an ALD chamber without breaking the vacuum.

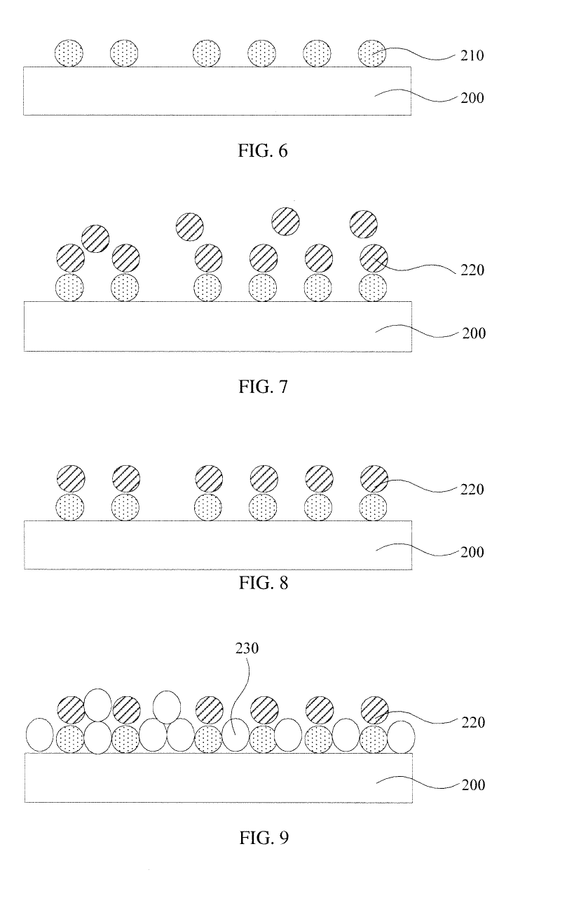

Firstly, referring to the step S20 and FIG. 5, a semiconductor substrate 200 is placed in an ALD chamber and an initial dielectric layer is formed thereon. The deposition chamber is a state-of-art reaction apparatus for ALD in the prior art. The operating temperature and pressure is in the range of 300-400° C. and <1 mTorr for forming the initial dielectric layer on the semiconductor substrate.

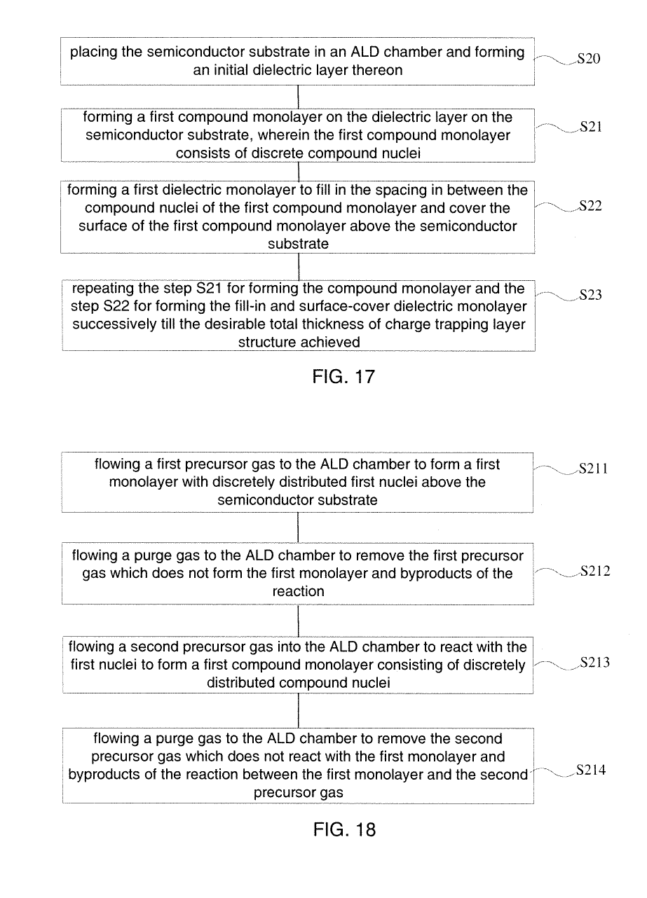

Referring to the step S21, forming a first compound monolayer on the semiconductor substrate with a initial dielectric layer formed thereon. As shown in FIG. 18, the step S21 further includes: step S211, flowing a first precursor gas to the ALD chamber to form a first monolayer with discretely distributed first nuclei above the semiconductor substrate; step S212, flowing a purge gas to the ALD chamber to remove the first precursor gas which does not form the first monolayer and byproducts of the reaction; step S213, flowing a second precursor gas into the ALD chamber to react with the first nuclei to form a first compound monolayer consisting of discretely distributed compound nuclei; step S214, flowing a purge gas to the ALD chamber to remove the second precursor gas which does not react with the first monolayer and byproducts of the reaction between the first monolayer and the second precursor gas.

Referring to the step S211 and FIG. 5, a first precursor gas flows to the ALD chamber. A first monolayer with discretely distributed first nuclei is formed on the dielectric layer on the semiconductor substrate 200 due to favored chemical energy for adsorption between the nucleation matter (such as metal) in the first precursor gas and the dielectric layer on the semiconductor substrate. There is much less favorable adsorption of the nucleation matter onto the nuclei of the first monolayer 210 already adsorbed on the semiconductor substrate 200 due to the less favorable adsorption between the atoms of the first precursor gas each other.

Usually, the first precursor gas includes a nucleation matter which is one of the desired elements to form a compound nucleus or compound clusters and diluted by a carrier gas. When the first precursor gas flows onto the substrate surface, the nucleation matter will be favorably absorbed and chemical bonded only with the atoms of dielectric layer (i.e. nuclei formation). The byproducts in precursors will be exhausted out of the ALD chamber with carrier gas. In conventional ALD process, the nucleation process is to be as fast as possible until the maximum amount of nuclei formed (i.e. saturation nucleation), so that later the desired film can be formed fast and dense with high quality. In contrast, in step S211, the density and distribution of these nuclei are controlled by utilizing slower nucleation rate by adjusting process parameters (i.e. pressure, time, temperature, flow rate, etc.), so that the first nuclei density is not reaching toward maximum (i.e. it is not in saturated manner). The slow nucleation process will also lead to very randomly and uniformly distributed nuclei on the substrate surface as a desirable feature in this disclosure.

The first precursor gas can be any of reaction gases having nucleation matter and capable of forming the first monolayer 210 on the dielectric layer on the semiconductor substrate 200 via chemical bonding or physical adsorption. The first precursor gas may include one or more of metal, semiconductor, metal compound coordinated with halogen and organic complex, or semiconductor compound coordinated with halogen or organic complex, or a combination thereof. For example, the metal materials may include Ta, Ti, W, Mo, Nb, Cu, Ni, Pt, Ru, Me, Ni, Hf, Zr, Al or the like, preferably Hf; the semiconductor may include Si, Ge, or the like, or a combination thereof; the metal compound coordinated with halogen or organic complex may include Al(CH₃)₃, Hf[N(CH₃)(C₂H₅)]₄, Hf[N(C₂H₅)₂]₄, Hf[OC(CH₃)₃]₄, or HfCl₄; and the semiconductor compound coordinated with halogen or organic complex may include SiCl₂H₂, Si(OC₂H₅)₄, Si₂Cl₆, SiH₂[NH(C₄H₉)]₂, SiH(OC₂H₅)₃ or the like.

In one embodiment according to the present invention, the metal in the metal compound coordinated with halogen and organic complex or the semiconductor in the semiconductor compound coordinated with halogen or organic complex acts as a nucleation matter. When the first precursor gas flows to the semiconductor substrate 200, a portion of the nucleation matters contained in the first precursor gas reacts with the surface of the dielectric layer to form a first monolayer with a discretely distribution of the nuclei, and the byproducts or remaining portion of the halogen or organic in the precursor gas will be exhausted out of the chamber.

As one illustrative example, the embodiment provides several particular precursor gases for well understanding and implementing the invention by those skilled in the art. If the compound monolayer to be formed is Si₃N₄, the first precursor gas is a reaction gas with Si atoms, such as SiCl₂H₂, SiH₄, Si₂Cl₆ or SiH₂[NH(C₄H₉)]₂ or the like.

As another illustrative example, If the compound monolayer to be formed is Hf-oxide, the first precursor gas is a reaction gas containing Hf atom, such as Hf[N(CH₃)(C₂H₅)]₄, Hf[N(C₂H₅)₂] ₄, Hf[OC(CH₃)₃]₄, or HfCl₄ or the like.

As another illustrative example, if the compound monolayer to be formed is Al₂O₃ layer, the first precursor gas is a reaction gas containing Al atom, such as Al(CH₃)₃ or the like.

As another illustrative example, if the compound monolayer to be formed is WN layer, the first precursor gas is a reaction gas containing W atom nucleation matter, such as WF₆, or the like.

In order that the nucleation matter in the first precursor gas reacts with the dielectric layer on the semiconductor substrate to form the first monolayer, the specific process conditions of the first precursor gas flowing to the deposition chamber should be controlled. The conditions controlling the discrete nuclei on the dielectric layer on the semiconductor substrate include the gas flow rate, process time, temperature, and pressure of the ALD chamber.

In this embodiment, the pressure plays a key role in achieving a monolayer with discretely distributed first nuclei. In the present invention, in order to allow the first precursor gas to form the first monolayer with discretely distributed nuclei on the dielectric layer on the semiconductor substrate, the process pressure, gas flow and process time of the first precursor gas flowing into the ALD chamber should be reduced (so that the nucleation rate is slow) with respect to the process parameters of forming a dense monolayer in prior art. Optionally, in an embodiment of the present invention, the flow rate of the first precursor gas in the deposition chamber can be greatly (or overly) decreased while the process time is properly increased as a compensation for maintaining the same rate of “slow” deposition, thereby improving the controllability of the process.

In this embodiment, the distribution density of the first nuclei in the first monolayer on the dielectric layer on the semiconductor substrate can be adjusted by controlling the process pressure, flow rate and time of the first precursor gas to the ALD chamber.

In the prior art, as to different first precursor gases, the process pressure, flow rate and process time required for forming a dense first monolayer on the semiconductor substrate are different; similarly, in the embodiment of present invention, as to different first precursor gases, the pressure, flow rate and time required for forming a first discrete monolayer on the semiconductor substrate are different. However, the process for forming a first monolayer according to the present invention is based on the process of forming a dense first monolayer in the prior art and is performed by slowing down the nucleation rate (by reducing the process pressure, flow rate and process time) of the first precursor gas correspondingly. In the process of forming a first monolayer according to the present invention, the first monolayer with a discrete and uniform distribution of nuclei can be formed with controllable density.

In the embodiment of the present invention, a first monolayer with discretely distributed first nuclei is formed on the dielectric layer on the semiconductor substrate 200 with a spacing in-between each other.

In one embodiment of the present invention, there is provided a particular example for implementing the invention by the skilled in the art. If the compound monolayer to be formed is Hf-oxide, the first precursor gas Hf[N(CH₃)(C₂H₅)]₄ flows into an ALD chamber at a flow rate of 0.01 slm -0.03 slm, and for 5 sec-10 sec. The temperature in the ALD chamber is within a range of 250° C. -450° C., and the pressure in the ALD chamber is less than 1 mTorr.

In another particular example, if the first compound monolayer to be formed is Al₂O₃, nitrogen gas carrying the liquid of Al(CH₃)₃ vapor is flowed into an ALD as the first precursor gas, the flow rate is 0.03 slm-0.15 slm, and the flow time is 0-10 sec,. The pressure in ALD chamber is in a range of 3 mTorr-5 mTorr, and the temperature in the deposition chamber is in a range of 250 slm −450° C., preferably 400° C.

Referring to the step S212 and the FIG. 6, a purge gas flows to the semiconductor substrate 200 in the ALD chamber to remove the remaining of the first precursor gas in the ALD chamber. The first precursor gas which is not adsorbed as first nuclei on the dielectric layer on the semiconductor substrate 200 is removed. In addition, those volatile byproducts of the reaction between the nucleation matter contained in the first precursor gas are removed. The purge gas includes He, Ne, Ar, dry N₂ or the like.

After purging by inert gas (e.g. dry N₂), the first monolayer 210 is formed on the dielectric layer on the semiconductor substrate with a discretely distributed first nuclei. Each nucleus is spaced apart with a spacing of 1 nm-3 nm.

The purging of the inert gas can be performed according to any of the conventional processes in the prior art. There is provided a particular example for implementing the invention by the skilled in the art, for example, N₂ gas flows into and purges the deposition chamber at a flow rate of 5 slm under a pressure of 1 Torr.

Referring to the step S213, a second precursor gas flows to the semiconductor substrate 200 in the ALD chamber, and reacts with the first nuclei in the first monolayer, thereby forming a first compound monolayer consisting of discretely distributed compound nuclei. As shown in FIG. 7, the second precursor gas flows to the semiconductor substrate in the ALD chamber, and preferably reacts with the first nuclei so as to form a compound monolayer 220. Due to the adsorption force between atoms, the second precursor gas atoms prefer to react with the first nuclei due to favorable chemical energy, and volatile byproducts may be generated from the reaction and be exhausted out of the ALD chamber.

Depending on the first compound monolayer to be formed and the first precursor gas, the second precursor gas can be any of the conventional substances in the prior art that can react with the first monolayer to generate the first compound monolayer nuclei in a discrete manner.

In a particular example, the second precursor gas is a material containing N, O, or S as oxidant, such as NH₃, N₂, O₂, H₂O, O₃, S₂ or the like.

As an illustrative example only, the embodiment provides several particular second precursor gases for well understanding and implementing the invention by the skilled in the art. If the first compound monolayer to be formed is Si₃N₄, the first precursor gas is a reaction gas having Si atom, and the second precursor gas is the gas that can react with the first monolayer formed by the first precursor gas to form a first compound monolayer, such as NH₃, N₂O, and N₂ or the like.

If the first compound monolayer to be formed is Hf-oxide, the first precursor gas is a reaction gas having Hf atoms, and the second precursor gas contains Oxygen to react with the first monolayer, such as O₃, N₂O, O₂, H₂O, or the like.

If the first compound monolayer to be formed is Al₂O₃, the first precursor gas is a reaction gas having Al atom, and the second precursor gas contains Oxygen to react with the first monolayer, such as O₃, N₂O, O₂, H₂O, or the like.

If the first compound monolayer to be formed is WN, the first precursor gas is a reaction gas having W atom, and the second precursor gas contains Nitrogen, for example, NH₃ or the like.

If the first compound monolayer to be formed is Zr-oxide, the first precursor gas is a reaction gas having Zr atom and the second precursor gas contains Oxygen, such as H₂O, O₃ or the like.

In one embodiment, the process of flowing the second precursor gas to the semiconductor substrate in the ALD chamber can be performed by any conventional techniques known to the skilled in the art. For example, when the first precursor gas is SiCl₂H₂ and the compound monolayer is Si₃N₄, NH₃ is used as the second precursor gas and injected into a conventional ALD apparatus in the prior art at a flow rate of 2-5 slm for 0-30 sec, while the pressure in the deposition chamber is 30-50 mTorr, and the temperature in the deposition chamber is 250° C.-450° C., preferably 400° C.

Referring to the step S214, a purge gas flows to the ALD chamber so as to remove the second precursor gas which does not react with the first monolayer and byproducts of the reaction between the first monolayer and the second precursor gas. As shown in FIG. 8, a purge gas flows to the semiconductor substrate 200 in the ALD chamber to remove the un-reacted remaining second precursor gas and volatile byproducts. The purge gas may include He, Ne, Ar, N₂ or the like.

After purging by the inert gases, a first compound monolayer 220 with discretely distributed compound nuclei is formed on the initial dielectric layer on the semiconductor substrate uniformly.

The process conditions for the purging by the inert gases (e.g. dry N₂) can be implemented by the skilled in the art, for example, N₂ can flow into and purge an ALD chamber at a flowing rate of 5 slm under a pressure of <1 Torr.

Referring the step S22, as shown in FIG. 9-13, a first dielectric monolayer 250 is formed above the semiconductor substrate 200 to fill the spacing between the compound nuclei and cover the first compound monolayer 220.

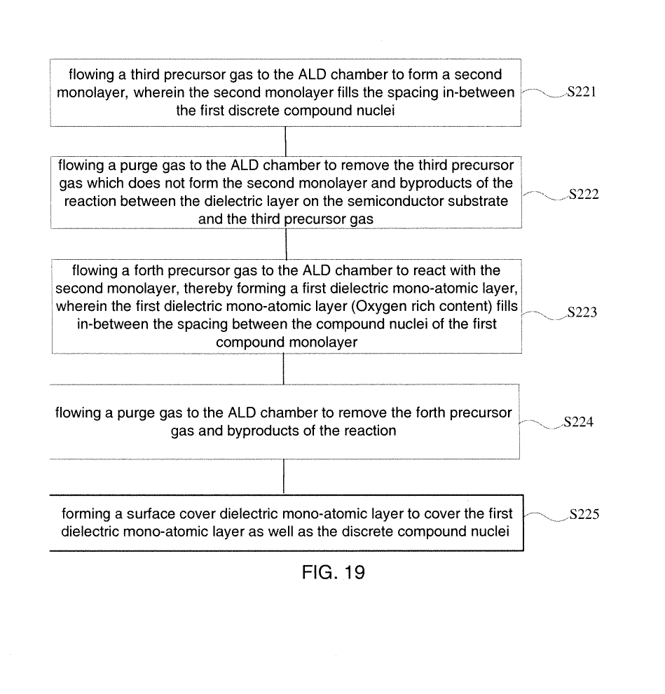

The process for forming the first dielectric monolayer to fill in the spacing in-between the first compound nuclei 220 and to cover the first dielectric mono-atomic layer and the discrete compound nuclei can beformed by ALD process. As shown in FIG. 19, in this embodiment, there is provided an ALD process with a saturation manner to form the first dielectric monolayer, which includes the following steps: step S221, flowing a third precursor gas to the ALD chamber to form a second monolayer, wherein the second monolayer fills the spacing in-between the first discrete compound nuclei; step S222, flowing a purge gas to the ALD chamber to remove the third precursor gas which does not form the second monolayer and byproducts of the reaction between the dielectric layer on the semiconductor substrate and the third precursor gas; step S223, flowing a forth precursor gas to the ALD chamber to react with the second monolayer, thereby forming a first dielectric mono-atomic layer, wherein the first dielectric mono-atomic layer (Oxygen rich content) fills in-between the spacing between the compound nuclei of the first compound monolayer; step S224, flowing a purge gas to the ALD chamber to remove the forth precursor gas and byproducts of the reaction; step S225, forming a surface cover dielectric mono-atomic layer to cover the first dielectric mono-atomic layer and to cover the discrete compound nuclei.

Referring to the step S221 and FIG. 9, a third precursor gas flows to the semiconductor substrate 200 in the ALD chamber. Since the first compound monolayer 220 has been formed on the initial dielectric layer on the semiconductor substrate 200, the nucleation matter in the third precursor gas forms a second monolayer 230 above the semiconductor substrate 200; furthermore, due to the discrete distribution of the compound nuclei of the first compound monolayer 220, the second monolayer 230 on the dielectric layer on the semiconductor substrate 200 fills in-between the spacing between the first compound nuclei. The nucleation matter in the third precursor gas positioned on the dielectric layer combines with the dielectric layer via inter-atomic force or chemical bonds. The third precursor gas can be any of the reaction gases that has nucleation matter in the prior art and can form the second monolayer on the dielectric layer on the semiconductor substrate through chemical adsorption. Furthermore, the nucleation matter in the third precursor gas can react with a forth precursor gas to form dielectric materials, such as Si-oxide, Si-nitride, Si-oxynitride, or the like, which is different from the compound nuclei.

For better understanding and implementing the invention by the skilled in the art, the embodiment provides several particular examples. If the dielectric layer to be formed is SiO₂, the fifth precursor gas can be Si(OC₂H₅)₄, SiH₂[NH(C₄H₉)]₂, SiH(OC₂H₅)₃, Si₂Cl₆, or SiHN[(CH₃)₂]₃ or the like.

The process of the third precursor gas flowing to the semiconductor substrate in the ALD chamber can be performed by any technique in the prior art known to those skilled in the art.

As one embodiment of the present invention, the third precursor gas flows into the atomic deposition chamber at a flow rate of 0.5 slm-5 slm, and for 10 sec-200 sec, and the temperature in the atomic deposition chamber is within a range of 250° C.-450° C., and the pressure in the ALD chamber is more than 10 mTorr.

Referring to the step S222 and FIG. 10, a purge gas flows to the semiconductor substrate 200 in the ALD chamber to remove the third precursor gas which does not form the second monolayer above the semiconductor substrate 200 and byproducts of the reaction between the nucleation matter contained in the third precursor gas and the initial dielectric layer on the semiconductor substrate 200. The purge gas can be He, Ne, Ar, dry N₂ or the like, and the process conditions of purging can be determined by those skilled in the art.

Referring to the step S223 and FIG. 11, a forth precursor gas flows into the ALD chamber and reacts with the second monolayer 230 to form a first dielectric mono-atomic layer 240.

The forth precursor gas reacts with the second monolayer 230 to form a first dielectric mono-atomic layer 240, which can be a layer of insulation materials such as Si-oxide, Ge-oxide or the like, thereby separating adjacent compound nuclei in the dielectric layer on the semiconductor substrate 200.

In an illustrative example, if the dielectric layer to be formed is SiO₂, the forth precursor gas flowing into the atomic deposition chamber can be NH₃, N₂O, N₂, O₂, S₂, N₂ or the like.

The process of the forth precursor gas flowing to the semiconductor substrate in the ALD chamber can be performed by any technique in the prior art known to those skilled in the art.

Referring to FIG. 12 and the step S224, a purge gas flows to the semiconductor substrate 200 in the ALD chamber to remove the forth precursor gas which does not react with the second monolayer 230 and byproducts of the reaction between the forth precursor gas and the second monolayer 230. The purge gas may be He, Ne, Ar, dry N₂ or the like, and the process conditions of purging can be determined by those skilled in the art.

After purging by the inert gas or dry nitrogen, the first dielectric mono-atomic layer 240 is formed on the dielectric layer on the semiconductor substrate 200, the first dielectric mono-atomic layer 240 fills the spacing in the compound nuclei of the compound monolayer.

Referring to the step S225 and FIG. 13, a surface cover dielectric mono-atomic layer is formed to cover the first dielectric mono-atomic layer and to cover the discrete compound nuclei.

As stated above, the dielectric mono-atomic layer fills in-between the compound nuclei of the compound monolayer is different from that of the dielectric mono-atomic layer covering the surface of the first compound monolayer. In this embodiment, the first dielectric mono-atomic layer for “fill-in” is Oxygen rich, such as Si-oxide, or Ge-oxide, while the “surface cover” dielectric mono-atomic layer (for covering the surface of the first compound monolayer and the first dielectric mono-atomic layer) is Nitrogen rich.

The “surface cover” dielectric mono-atomic layer can be a single layer or multi-layers. In order that more charge trapping sites are generated in the charge trapping layer, the “surface cover” dielectric mono-atomic layer is a single layer and thus more layers of compound monolayer may be formed. The process for forming the surface cover dielectric mono-atomic layer on the first dielectric mono-atomic layer 240 and on the compound monolayer is similar to the process for forming the first dielectric mono-atomic layer, as described in steps S221-S224 and the FIGS. 9-12. Note that, the dielectric mono-atomic layer for surface-covering contains more Nitrogen, such as Si-oxy-nitrogen, which is different from that of the first dielectric for “fill-in” mono-atomic layer 240. The surface cover dielectric mono-atomic layer and the first dielectric mono-atomic layer 240 together consist of a first dielectric monolayer 250 as shown in FIG. 13.

In the process described in the embodiment, after forming the first compound monolayer, the first dielectric monolayer 250 is formed on the first compound monolayer to cover and seal the first discrete compound nuclei in the first compound monolayer. If necessary, the processes of forming the compound monolayer and the step of forming the first dielectric monolayer can be repeatedly performed for multiple times.

Referring to the step S23, repeating the step S21 for forming the compound monolayer and the step S22 for forming the first dielectric monolayer successively till the resulting structure has a predetermined thickness. FIG. 14 shows a second compound monolayer 270 with a discrete distribution of second compound nuclei formed on the first dielectric monolayer 250 and on the first compound monolayer 220. It should be noted that in this embodiment, the second compound monolayer 270 will randomly align on the first dielectric monolayer 250, and will not just aligns above the top of the first compound monolayer 220, due to the existence of the “surface-cover” first dielectric mono-atomic layer.

Furthermore, material of the first compound monolayer 220 and that of the second compound monolayer 270 may be the same or different from each other. Preferably, material of the first compound monolayer is the same as that of the compound monolayer formed later. In this embodiment, the first compound monolayer and the second compound monolayer can be made of Si-nitride, Al-oxide, Hf-oxide, W-nitride and the like.

Moreover, FIG. 14 also shows a second dielectric monolayer 280 formed filling in the spacing between the second compound nuclei and covering the in-fill dielectric material and covering the second compound monolayer 270. The process for forming the second dielectric monolayer 280 can be performed by any techniques well known to those skilled in the art, such as PVD process, CVD process and the like. As an embodiment, ALD process is performed to form the second dielectric monolayer, which can refer to the process for forming the first dielectric monolayer.

If necessary, after the first compound monolayer, the first dielectric monolayer, the second compound monolayer and the second dielectric monolayer are formed above the semiconductor substrate, a third compound monolayer may be formed on the second dielectric monolayer, and a third dielectric monolayer may be formed above the second dielectric monolayer to fill in the spacing and cover the third compound monolayer; in the same way, a (N+1)^{th} compound monolayer may be formed on the N^{th} dielectric monolayer, and a (N+1)^{th} dielectric monolayer may be formed above the N^{th} dielectric monolayer to cover the (N+1)^{th} compound monolayer, where the N is an integer, typically 3-4, so that a plurality of compound monolayers and a plurality of dielectric monolayers covering respective compound monolayer can be formed above the semiconductor substrate.

The process for forming the (N+1)^{th} compound monolayer can be the same as that for the first compound monolayer, also, the material of the (N+1)^{th} compound monolayer can be the same as that of the first compound monolayer.

One or more compound monolayers and dielectric monolayers can be formed above the semiconductor substrate by the ALD process provided in the embodiment. The dielectric monolayers isolating compound nuclei from each other in one compound monolayer and isolating compound monolayers from each other.

In the above embodiment of the present invention, the size and the thickness of each cluster inlayed in the dielectric material is substantially the same as that of compound nuclei in the compound monolayer. In another embodiment of the present invention, the thickness of each cluster inlayed in the charge-trapping-layer is a multiple integer of compound nuclei's thickness, so as to strengthen the maintenance of charges in the compound clusters.

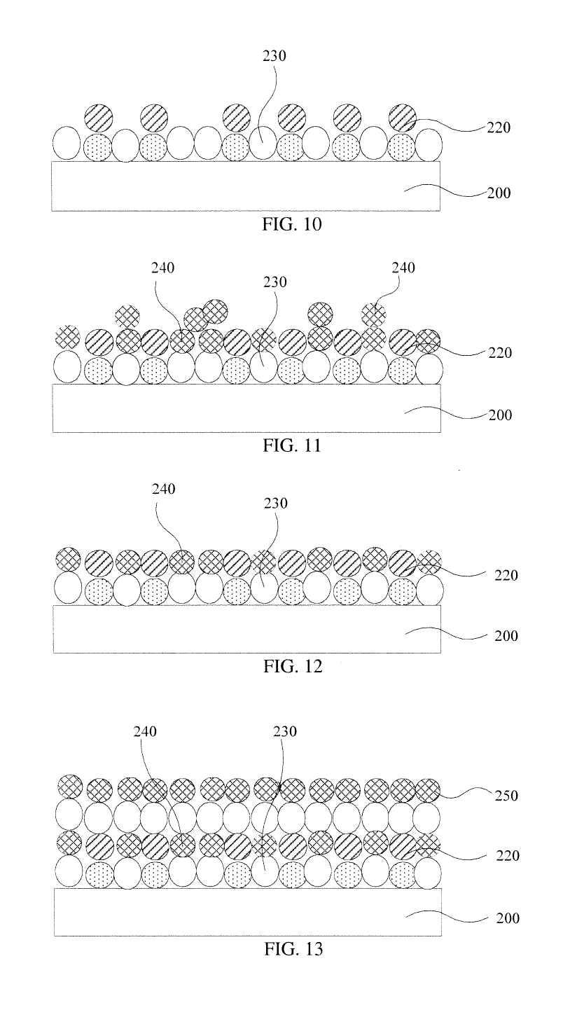

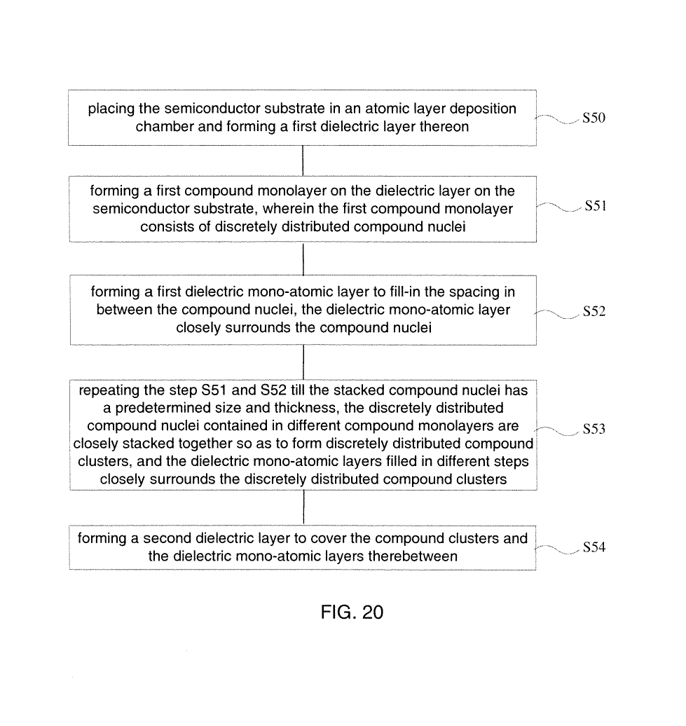

Specifically, referring to FIG. 20 and FIG. 15, the charge-trapping-layer with a multiple integer of compound nuclei's thickness can be formed as following: step S50, placing the semiconductor substrate in an atomic layer deposition chamber and forming a first dielectric layer thereon; step S51, forming a first compound monolayer on the dielectric layer on the semiconductor substrate, wherein the first compound monolayer consists of discretely distributed compound nuclei; step S52, forming a first dielectric mono-atomic layer to “fill-in” the spacing in between the compound nuclei, the dielectric mono-atomic layer closely surrounds the compound nuclei; step S53, repeating the step S51 and S52 till the stacked compound nuclei has a predetermined size and thickness, the discretely distributed compound nuclei contained in different compound monolayers are closely stacked together so as to form discretely distributed compound clusters, and the dielectric mono-atomic layers filled in different steps closely surrounds the discretely distributed compound clusters; step S54, forming a second dielectric layer to cover the compound clusters and the dielectric mono-atomic layers therebetween.

As shown in FIG. 15, a semiconductor substrate 300 is provided with a first dielectric layer (not shown) formed thereon. A first compound monolayer 320 is formed above the semiconductor substrate 300 containing discretely distributed compound nuclei. A first dielectric mono-atomic layer 330 is formed to fill-in the spacing in between the discrete compound nuclei in the first compound monolayer 320, the dielectric mono-atomic layer 330 closely surrounds the compound nuclei; The first compound monolayer 320 and the first dielectric mono-atomic layer 330 are repeatedly formed. The discretely distributed compound nuclei contained in different compound monolayers are directly stacked on top of each other so as to form discretely distributed compound clusters, and the dielectric mono-atomic layers formed in different steps closely surrounds the discretely distributed compound clusters. A surface cover dielectric mono-atomic layer 350 is formed to cover the compound clusters and to cover the dielectric mono-atomic layers filled in-between the spacing of the compound clusters.

It should be noted that in the step S53, the compound monolayer will preferably stack on top of prior compound monolayer due to favored chemical energy. Similarly, the dielectric monolayer will also preferably stack on top of prior dielectric monolayer. The species of monolayers can be purposely selected with suitable chemical energy.

If necessary, repeating the step S51 to S54 till the resulting charge trapping layer structure has a predetermined thickness. As an illustration, the compound clusters and the dielectric mono-atomic layer are repeatedly formed twice as shown in FIG. 15.

As stated above, the dielectric mono-atomic layer fills in-between the compound nuclei of the compound monolayer is Oxygen rich, such as Si-oxide, or Ge-oxide, while the “surface cover” dielectric mono-atomic layer (for covering the surface of the first compound monolayer and the first dielectric mono-atomic layer) is Nitrogen rich.

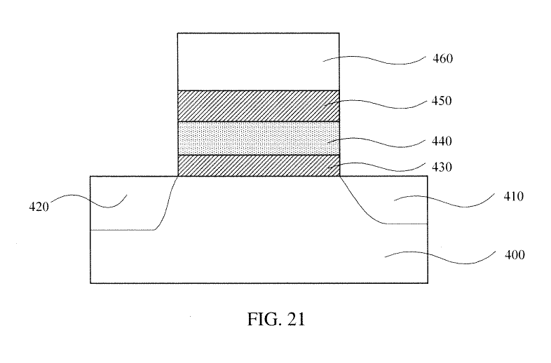

The present invention further provides a semiconductor NVM device according to the method of an embodiment stated above. As shown in FIG. 21, The semiconductor NVM device including: a semiconductor substrate 400; a three layer stack structure of medium dielectric layer 430-charge trapping layer 440-medium dielectric layer 450 disposed on the semiconductor substrate; a gate 460 disposed above the three-layer stack structure; a source 410 and a drain 420 disposed in the semiconductor substrate at opposite sides of the three-layer stack structure; wherein the charge trapping layer is a dielectric layer containing one or more discrete compound clusters formed by ALD method. Here the word “containing” means that the one or more discrete compound clusters are embedded in dielectric layers and covered by the same. The semiconductor substrate 400 may include silicon (Si) or silicon germanium (SiGe) with monocrystal or polycrystal structure, ion-doped Si or SiGe such as N-doped or P-doped Si or SiGe, compound semiconductor such as silicon carbide, indium antimonide, lead telluride, indium arsenide, indium phosphide, gallium arsenide or gallium telluride, alloy semiconductor or a combination thereof, or silicon-on-insulator (SOI).

In the three layer stack structure, material of the dielectric layer 430 or 450 may include dielectric material, such as Si-oxide, Si-nitride, Ge-oxide, Ge-nitride, Al-oxide or the like; the charge trapping layer 440 can be a dielectric layer containing one or more discrete compound clusters, and the dielectric layer is made of dielectric materials such as Si-oxide, Si-nitride, and Si-oxynitride; the discrete compound clusters are sealed in dielectric layer with or without direct stacking; the compound clusters can be any of the substance used for trapping charges in a charge trapping layer of a metal, or semiconductor or their oxides NVM device as described previously.

As described in above embodiment, the compound clusters are formed at an unsaturation manner by ALD method, by which the compound clusters are formed by stacking one or more compound monolayer, wherein each of the compound monolayer comprises discretely distributed compound nuclei. Therefore, each of the discrete compound clusters is formed by stacking one or more compound nuclei together, and the size of each of the discrete compound cluster is at an atomic level. The discrete compound clusters has a density of more than 1×10¹⁴ cm⁻² and less than 5×10¹⁵ cm⁻².

In one embodiment, each of the discrete compound clusters consists of one compound nucleus, thereby maximizing the density of the clusters in the dielectric layer so as to trap more charges. The size and thickness of each of the discrete compound clusters is substantially the same as that of compound nucleus in the compound monolayer. In this condition, each of the discrete compound clusters has a size ranging from 3 nm-7 nm, a thickness ranging from 1 nm-10 nm.

The process for forming the compound clusters can be referred to above embodiments. As stated above, the compound clusters are formed by stacking one or more layer of compound monolayer which consists of discretely distributed compound nuclei. In one embodiment, the compound clusters are different in material in different compound monolayers.

In another embodiment, the compound clusters are the same in material in different compound monolayers.

The discrete compound cluster is selected from a group of materials consisting of Si-nitride, Al-oxide. Hf-oxide or W-nitride, preferably, Hf-oxide.

In another embodiment, each of the discrete compound clusters consists of a plurality of compound nuclei, preferably three to four compound nuclei, stacking together in order to strengthen the maintenance of the charges trapped in the charge-trapping-layer, that is, the thickness of each cluster inlayed in the charge-trapping-layer is a multiple integer of a compound nucleus's thickness. Each of the discrete compound clusters has a size ranging from 3-7 nm and a thickness ranging from 1 nm-10 nm.

The dielectric material includes two portions: the first portion is the dielectric material “filling” in-between the discretely distributed compound clusters of one compound monolayer, the second portion is the dielectric material “covering” the compound clusters and the filling-in dielectric material in-between adjacent compound clusters of one compound monolayer. The precursor to form the dielectric material typically includes Si, Oxygen, and Nitrogen species (to form Si-oxide, or Si-nitride, or mixture Si-oxynitride). It should be noted that the dielectric material with more Oxygen content can be favorable to fill-in the gap of adjacent compound clusters formed in one compound monolayer; alternatively, the dielectric material with more Nitrogen content will be favorable to cover the top surface of the compound clusters and to cover the fill-in dielectric material.

In one embodiment of the present invention, the dielectric layer includes Si-oxide, Si-nitride, Ge-xide, Ge-nitride, or Al-oxide. The materials of the dielectric layer and that of the compound clusters are different from each other.

Material of the gate 460 may be a multilayer structure containing semiconductor materials, including Si, Ge, metal or a combination thereof.

The source 410 and the drain 420 are located at either side of the three layer stack structure, and are in the semiconductor substrate 400. Referring to FIG. 21, the position of the source 410 and the drain 420 may be exchanged with each other, and the doping ions may be one or more of phosphorus ion, arsenic ion, boron ion, or indium ion.

In the semiconductor non-volatile memory device provided by the embodiment, the charge trapping layer 440 includes discretely distributed compound clusters, and the compound cluster has a size at atomic level, typically 3 nm-7 nm, and the height (or thickness) are controllable, the compound clusters are formed by stacking compound nuclei together contained in different compound monolayers. Furthermore, the distribution density of the discretely distributed compound dots can be controlled through controlling the ALD process for forming the compound monolayer with discretely distributed compound nuclei.

The embodiments of the present invention is capable of improving the maintenance of the charge trapped in the charge trapping layer and the charge trapping capability, even if the semiconductor non-volatile memory device has a small line width.

While the present invention has been described with respect to certain preferred embodiments, it will be apparent to those skilled in the art that various changes and modifications may be made without departing from the spirit and scope of the invention as defined in the following claims.

What is claimed is:

1. A semiconductor non-volatile memory (NVM) device, comprising:
a semiconductor substrate;
a three-layer stack structure of medium layer-charge trapping layer-medium layer disposed on the semiconductor substrate;
a gate disposed above the three-layer stack structure; and
a source and a drain disposed in the semiconductor substrate at opposite sides of the three-layer stack structure;
wherein the charge trapping layer is a dielectric layer containing one or more discrete compound clusters formed by atomic layer deposition method.

2. The semiconductor NVM device in claim 1, wherein the size of each of the discrete compound cluster is at an atomic level.

3. The semiconductor NVM device in claim 1, wherein the discrete compound clusters has a density of greater than 1×10¹⁴ cm⁻² and less than 5×10¹⁵ cm⁻².

4. The semiconductor NVM device in claim 1, wherein each of the discrete compound clusters has a thickness ranging from 1 nm to 10 nm.

5. The semiconductor NVM device in claim 1, wherein each of the discrete compound clusters has a size ranging from 3 nm to 7 nm.

6. The semiconductor NVM device in claim 1, wherein spacing among the discrete compound clusters is 1 nm to 3 nm.

7. The semiconductor NVM device in claim 1, wherein the dielectric material comprises a portion of dielectric material filling in a gap in-between adjacent discrete compound clusters, the dielectric material filling in a gap between adjacent discrete compound clusters being oxygen rich.

8. The semiconductor NVM device in claim 7, wherein the portion of dielectric material filling in a gap between the adjacent discrete compound clusters is Si-oxide, Ge-oxide or Al-oxide.

9. The semiconductor NVM device in claim 1, wherein the dielectric material comprises a portion of dielectric material covering the discrete compound clusters and covering the dielectric material filling in a gap between the adjacent discrete compound clusters, the dielectric material covering the discrete compound clusters and covering dielectric material filling in a gap between the adjacent discrete compound clusters being Nitrogen rich.

10. The semiconductor NVM device in claim 9, wherein the dielectric material covering the discrete compound clusters and covering the dielectric material filling in a gap between the adjacent discrete compound clusters formed in one compound monolayer is Si-Nitride, Ge-Nitride, or Al-Nitrogen.

11. The semiconductor NVM device in claim 1, wherein each of the discrete compound clusters comprises one compound nuclei.

12. The semiconductor NVM device in claim 1, wherein each of the discrete compound cluster comprises a plurality of compound nuclei.

13. The semiconductor NVM device in claim 1, wherein each of the discrete compound clusters comprises 3 to 4 compound nuclei.

14. The semiconductor NVM device in claim 1, the thickness of each discrete compound cluster inlayed in the charge trapping layer is a multiple integer of a compound nucleus's thickness.

15. The semiconductor NVM device in claim 1, wherein the discrete compound clusters are different in material in different layers.

16. The semiconductor NVM device in claim 1, wherein the discrete compound clusters are the same in material in different layers.

17. The semiconductor NVM device in claim 1, wherein the discrete compound cluster is selected from the group of materials consisting of Si-nitride, Al-oxide, Hf-oxide and W-nitride.

18. The semiconductor NVM device in claim 1, wherein the discrete compound cluster is hafnium oxide.
